(19) United States
(12) Patent Application Publication
(10) Pub. No.: US 2021/0335689 A1
(43) Pub. Date: Oct. 28, 2021

(54) SEMICONDUCTOR POWER DEVICE WITH PRESS-FIT MOUNTING

(71) Applicant: Vitesco Technologies USA, LLC, Auburn Hills, MI (US)

(72) Inventors: Irving Uriel Hernandez Orozco, Rochester, MI (US); Kevin D Moore, Bloomfield Hills, MI (US)

(73) Assignee: Vitesco Technologies USA, LLC, Auburn Hills, MI (US)

(21) Appl. No.: 16/858,204

(22) Filed: Apr. 24, 2020

(51) Int. Cl. H01L 23/367; H01L 23/00; H01L 23/31

(52) U.S. Cl. CPC H01L 23/367; H01L 23/3114; H01L 24/29; H01L 24/45

(57) ABSTRACT

A semiconductor device, includes a housing; at least one semiconductor die which forms at least one semiconductor component, the semiconductor die being disposed within the housing; one or more first pins extending from the housing; and one or more bond wires electrically connecting the one or more first pins with the at least one semiconductor component. A heat slug is thermally coupled to the semiconductor die and at least partly disposed within the housing. One or more second pins extends from the housing and is connected to the heat slug. An electronics device includes a printed circuit board and the semiconductor device connected thereto.

### FIELD OF INVENTION

The present invention generally relates to semiconductor packaging, and particularly to packaging for semiconductor devices for attachment to a printed circuit board (PCB).

### BACKGROUND

There are known power semiconductor devices which are disposed in packages that conform to various packaging standards utilizing through-hole and surface-mount technologies. Packages which are utilized by power semiconductor devices include, for example, TO-247 (FIG. 1) and TO-263 (FIG. 2). The TO-247 package includes through-hole leads 10 and a through-hole 12 for attachment to an external heat sink. The TO-263 package include surface mount leads 20 and a heat slug 22 disposed along the bottom of the package.

In a number of instances, power semiconductor devices using conventional packages undesirably result in a more complex assembly process for attaching a heat sink and for assembly of an electronics device incorporating the power semiconductor device. Some conventional packages also limit the use of semiconductor devices that are rated for surface mount technology (SMT) temperature processing. Further, conventional power semiconductor packages utilizing through-hole technology (THT) occupy a larger space on a PCB due to device manufacturer recommendations for providing mechanical support for the lead base.

### SUMMARY

Example embodiments overcome the deficiencies of known packages for power semiconductor devices and satisfy a need for an improved semiconductor device package. According to an example embodiment, there is disclosed a power semiconductor device, including: a housing; a semiconductor die forming at least one semiconductor component, the semiconductor die being disposed within the housing; and one or more first pins extending from the housing. One or more bond wires electrically connect the one or more first pins with the semiconductor die. A heat slug is thermally coupled to the semiconductor die and at least partly disposed within the housing. One or more second pins coupled to the housing which are not connected to a bond wire or to the at least one semiconductor component.

Each of the one or more first pins and the one or more second pins includes a compliant pin configured for providing a press-fit connection with a printed circuit board when partly inserted therein.

The semiconductor die is attached to the heat slug with a thermally conductive adhesive.

The one or more second pins is thermally connected to the heat slug. In one aspect, each second pin extends from the heat slug at a location external to the housing. In another aspect, each second pin extends from or is thermally connected to the heat slug at a location internal to the housing.

The housing includes an encapsulant formed or molded over the semiconductor die.

The heat slug is disposed along a top portion of the housing. A surface of the heat slug is exposed for attachment of an external heat sink thereto.

According to another example embodiment, an electronics device includes a printed circuit board and a plurality of electrical or electronic components connected to the printed circuit board. A first electrical or electronic component of the plurality of electrical or electronic components includes a housing, a semiconductor die forming at least one semiconductor component, the semiconductor die being disposed within the housing, one or more first pins extending from the housing, and one or more bond wires electrically connecting the one or more first pins with the semiconductor die. A heat slug is thermally coupled to the semiconductor die and at least partly disposed within the housing. One or more second pins is connected to the heat slug.

### BRIEF DESCRIPTION OF THE DRAWINGS

Aspects of the invention will be explained in detail below with reference to exemplary embodiments in conjunction with the drawings, in which:

FIG. 1 is a perspective view of a conventional power semiconductor device;

FIG. 2 is a perspective view of another conventional power semiconductor device;

FIG. 3 is a perspective view of a semiconductor device according to an example embodiment;

FIG. 4 is a cross-sectional view of the semiconductor device of FIG. 3;

FIG. 5 is a perspective view of a semiconductor device according to another example embodiment;

FIG. 6 is a cross-sectional view of the semiconductor device of FIG. 5;

FIG. 7 is a cross-sectional view of a semiconductor device according to yet another example embodiment; and

FIG. 8 is a partial perspective view of an electronics device incorporating semiconductor devices of FIGS. 3 and 5, according to another example embodiment.

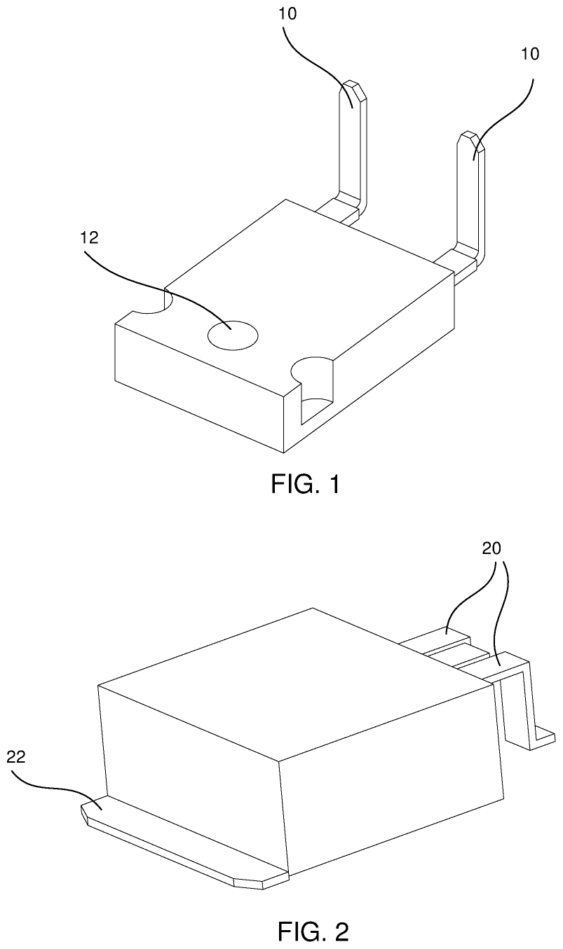

### DETAILED DESCRIPTION

The following description of the example embodiment(s) is merely exemplary in nature and is in no way intended to limit the invention, its application, or uses. In the figures and throughout the detailed description, the same reference numbers are used to identify identical or similar elements. For the sake of clarity, the elements are not shown to scale unless otherwise specified.

The example embodiments are generally directed to a semiconductor device, such as a power semiconductor device, having compliant pins and a heat slug that is also connected to a compliant pin. With the heat slug disposed in the upper portion of the semiconductor device, heat dissipation from the semiconductor device is improved and heat dissipation strategies are simplified. The semiconductor device provides a more robust and more cost effective assembly of an electronics device which utilizes the semiconductor device.

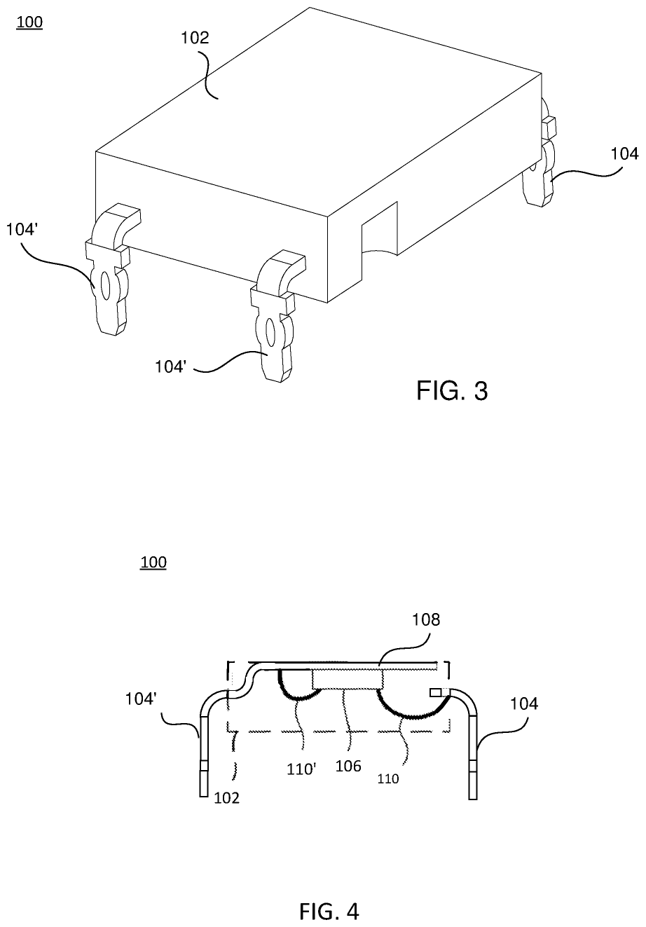

FIGS. 3 and 4 illustrate a semiconductor device 100 according to an example embodiment which is based upon a TO-247 package. In one implementation, semiconductor device 100 is a power semiconductor device, such as a power transistor or power diode configured, for example, for use in automotive applications. It is understood, however, that semiconductor device 100 may be a device other than a power semiconductor device. As illustrated, semiconductor device 100 includes a housing 102 which may, for example, be a molded plastic material which partly or wholly surrounds or otherwise encapsulates components of the semiconductor device, as is well known in the art. It is understood that housing 102 may be constructed from another material such as glass, metal and ceramic.

Semiconductor device 100 further includes pins 104 which extend from housing 102 and are configured to connect to a PCB. Pins 104 provide electrical connections to a semiconductor die 106 within housing 102. Instead of being through-hole or surface mounted pins, pins 104 are compliant pins which provide a press-fit engagement with the PCB. A lengthwise portion of each pin 104 is resiliently compressible in the lateral direction such that during insertion of the pin portion in an aperture defined in the PCB, the portion compresses laterally inwardly and after insertion presents a laterally outwardly force against the PCB aperture to create the press-fit engagement with the PCB. In the example embodiments illustrated, the pins 104 are located on, and extend from, opposed sides of housing 102, but it is understood that pins 104 may extend from more or less sides of housing 102.

As shown in FIG. 4, semiconductor device 100 includes semiconductor die 106 which forms the semiconductor component(s) of semiconductor device 100. Semiconductor die 106 is connected to a die attach and/or heat slug 108 using a thermally conductive adhesive (not shown). Heat slug 108 serves to dissipate heat from semiconductor die 106. Heat slug 108 may be constructed from metal of other thermally conductive material and may be part of the leadframe of semiconductor device 100. In the illustrated embodiment, heat slug 108 is disposed at or near the upper surface of housing 102. In an embodiment, housing 108 does not cover heat slug 108 such that an upper surface of heat slug is exposed, and an another embodiment heat slug 108 is covered by housing 102. It is understood that heat slug 108 may be disposed in locations other than at or near the top of semiconductor device 100.

Semiconductor device 100 further includes electrically conductive bond wires 110, each of which connects a bond pad of semiconductor die 106 to a pin 104 so as to provide an external electrical connection to semiconductor die 106. At least one bond wire 110′ connects a bond pad of semiconductor die 106 to heat slug 108. The bond pad of semiconductor die 106 to which bond wire 110′ is connected may be configured to be connected to ground. As shown in FIG. 4, semiconductor die 106 and bond wires 110, 110′ are disposed within housing 102.

In the example embodiment shown in FIGS. 3 and 4, pins 104′ are connected to heat slug 108. In particular, pins 104′ are connected to heat slug 108 within housing 102. This connection provides for an electrical and thermal coupling between heat slug 108 and pins 104′. By inserting pins 104′ within an aperture of a PCB which is connected to one or more ground planes within the PCB, the PCB provides heat sinking capability from semiconductor die 106 which is attached to heat slug 108, and suitably connects the desired bond pad of semiconductor die 106 to ground.

Though semiconductor device 100 of FIGS. 3 and 4 depicts two pins 104′ which are connected to heat slug 108, it is understood that more or less than two pins 104′ may be connected to heat slug 108.

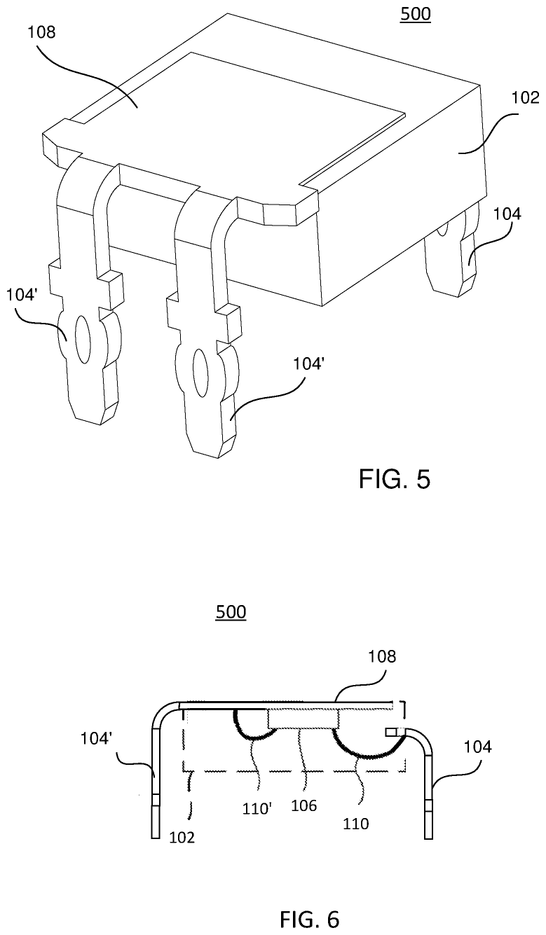

FIGS. 5 and 6 illustrate a semiconductor device 500 according to another example embodiment which is based on a TO-263 (D2Pak) package. Semiconductor device 500 includes a housing 102 as discussed above. Also included is semiconductor die 106 which forms the semiconductor component(s) and is connected via thermally conductive adhesive to die attach and/or heat slug 108. Instead of surface mount pins which are part of a TO-263 package, pins 104 and 104′ are compliant pins for providing a press-fit engagement with a PCB. Bond wires 110 are connected between bond pads on semiconductor die 106 and pins 104, and at least one bond wire 110′ is connected between at least one bond pad on semiconductor die 106 and heat slug 108.

Semiconductor device 500 further includes one or more pins 104′ which are connected to heat slug 108. In particular, pins 104′ are connected to heat slug 108 within housing 102. This connection provides for an electrical and thermal coupling between heat slug 108 and pins 104′. By inserting pins 104′ within an aperture of a PCB which is connected to one or more ground planes within the PCB, the PCB provides heat sinking capability from semiconductor die 106 which is attached to heat slug 108, and suitably grounds the desired bond pad of semiconductor die 106. Though semiconductor device 100 of FIGS. 3 and 4 depict two pins 104′ which are connected to heat slug 108, it is understood that more than or less than two pins 104′ may be connected to heat slug 108.

In contrast to semiconductor device 100 of FIGS. 3 and 4, pins 104′ of semiconductor 500 connect to heat slug 108 external to housing 102. As shown in FIGS. 5 and 6, pins 104′ connect to heat slug 108 at or near an upper edge of housing 102.

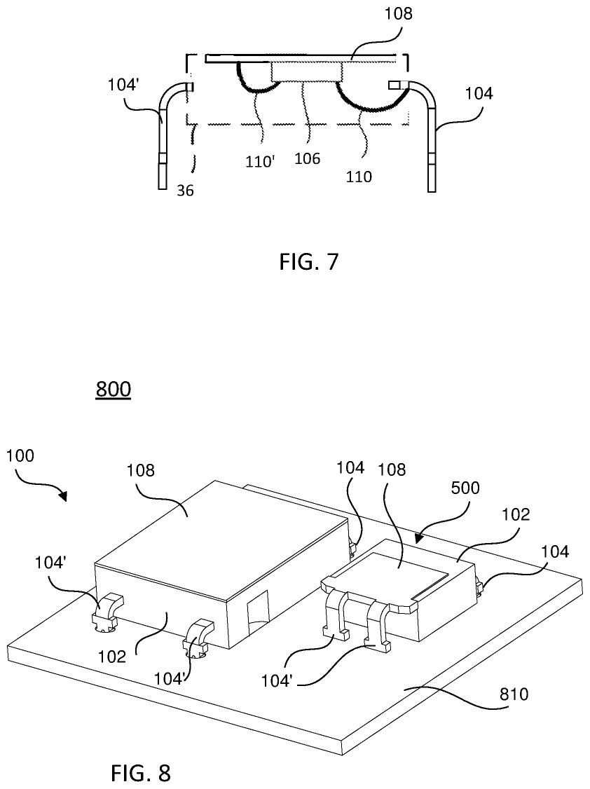

Semiconductor devices 100 and 500 include pins 104′ connected to heat slug 108 internally and externally to housing 102, respectively. In another embodiment shown in FIG. 7, pins 104′ are not connected to heat slug 108 and instead simply serve to stabilize the semiconductor device relative to a PCB. In this embodiment, a bond wire may be connected between pins 104′ and at least one bond pad on semiconductor die 106 configured to be connected to the ground reference.

FIG. 8 illustrates an electronics device 800 according to another example embodiment. As illustrated, electronics device 800 includes semiconductor device 100 as well as semiconductor device 500. Semiconductor devices 100 and 500 are disposed on PCB 810, which may include additional electrical or electronic components, assemblies, subassemblies, sockets, and/or other devices disposed thereon (not shown). PCB 810 may include a number of laminated layers with electrically conductive traces (not shown) which provide electrical connectivity between the components disposed on the PCB. It is understood that PCB 810 may be larger relative to the size of semiconductor devices 100 and 500, and that PCB 810 is illustrated in FIG. 8 for reasons of simplicity.

The use of compliant pins 104, and particularly pins 104′ which are electrically and thermally connected to heat slug 108, provide a number of advantages. For example, through-hole pins provide for a longer distance from PCB 810 to semiconductor die 106 than the distance provided by pins 104 due to the required mechanical support on the through-hole leads, according to recommendations by component manufacturers. Compliant pins 104 provide a shorter distance. For applications with higher operating frequencies such as power transformation devices (e.g., DC-to-DC converters), a shorter distance from semiconductor die 106 to PCB 810 is desired, with longer distances resulting in lower electrical efficiency of electronics device 800. The use of semiconductor devices 100 and 500 thus results in less space occupied on PCB 810.

Applications with higher power levels benefit from the use of larger package sizes for the same electronics device. Through-hole component packages such as TO-220 and TO-247 are a common choice. However, the use of these devices/packages complicates the manufacturing process because a clamping component (e.g., a screw or clip) is usually required to achieve a proper contact with a heat sink external to the electronics device. A press-fit mounting solution for semiconductor devices 100 and 500 as discussed above yields a lower bill of materials cost because the devices 100, 500 are already constrained to PCB 810 such that heat sinks can be more easily connected to housing 102 and/or heat slug 108 of devices 100, 500.

Especially with respect to conventional surface-mount semiconductor devices, semiconductor devices 100, 500 provide a much more efficient heat sink solution with heat slugs 108 exposed along the top of the semiconductor device. Some known packages with heat slugs disposed on the top of the package housing are available but they require a support method to limit lead deformation and/or solder stress during final assembly. This disadvantageously results in an imbalanced mechanical support compared to traditional surface-mount technology devices in which the heat slug 108 is also soldered to the PCB.

The use of press-fit compliant pins 104 (including pins 104′) as described above reduces the number of solder operations during manufacturing of electronics device 800. This reduces or otherwise eliminates the exposure time at elevated temperatures for electronics device 800 and its components, assemblies, etc. during manufacturing.

Further, when attaching an external heat sink to electronics device 100 or 500, vertical variation of the heat sink position may be better controlled due to the ability to use automatic press equipment.

The semiconductor devices 100 and 500 are described above as being based upon particular conventional packages. It is understood that semiconductor devices according to other embodiments may be based upon other conventional package types. In addition, it is understood that the die attach to which semiconductor die 106 is attached may be a separate element from heat slug 108 though thermally coupled thereto, and in some embodiments the die attach may be spaced apart from heat slug 108. It is further understood that each semiconductor device may include more than one semiconductor die which form the semiconductor component(s) of the semiconductor device. Such semiconductor die may, for example, be placed adjacent each other on the die attach.

The example embodiments have been described herein in an illustrative manner, and it is to be understood that the terminology which has been used is intended to be in the nature of words of description rather than of limitation. Obviously, many modifications and variations of the invention are possible in light of the above teachings. The description above is merely exemplary in nature and, thus, variations may be made thereto without departing from the spirit and scope of the invention as defined in the appended claims.

What is claimed is:

1. A semiconductor device, comprising:
a housing;
a semiconductor die forming at least one semiconductor component, the semiconductor die being disposed within the housing;
one or more first pins extending from the housing;
one or more bond wires electrically connecting the one or more first pins with the semiconductor die;
a heat slug thermally coupled to the semiconductor die and at least partly disposed within the housing; and
one or more second pins coupled to the housing and not connected to a bond wire or to the at least one semiconductor die.

2. The semiconductor device of claim 1, wherein each of the one or more first pins and the one or more second pins comprises a compliant pin configured for providing a press-fit connection with a printed circuit board when partly inserted therein.

3. The semiconductor device of claim 1, wherein the semiconductor die is attached to the heat slug with a thermally conductive adhesive.

4. The semiconductor device of claim 1, wherein the one or more second pins is thermally connected to the heat slug.

5. The semiconductor device of claim 4, wherein each second pin extends from the heat slug at a location external to the housing.

6. The semiconductor device of claim 4, wherein each second pin extends from or is thermally connected to the heat slug at a location internal to the housing.

7. The semiconductor device of claim 1, wherein the housing comprises an encapsulant formed around the semiconductor die.

8. The semiconductor device of claim 1, wherein the heat slug is disposed along a top portion of the housing.

9. The semiconductor device of claim 1, wherein a surface of the heat slug is exposed for attachment of an external heat sink thereto.

10. An electronics device, comprising:
a printed circuit board;
a plurality of electrical or electronic components connected to the printed circuit board;
a first electrical or electronic component of the plurality of electrical or electronic components comprises
a housing,
a semiconductor die forming at least one semiconductor component, the semiconductor die being disposed within the housing,
one or more first pins extending from the housing,
one or more bond wires electrically connecting the one or more first pins with the semiconductor die,
a heat slug thermally coupled to the semiconductor die and at least partly disposed within the housing, and
one or more second pins connected to the heat slug.

11. The electronics device of claim 10, wherein each of the one or more first pins and the one or more second pins comprises a compliant pin configured for providing a press-fit connection with an aperture defined in a printed circuit board when partly inserted therein.

12. The electronics device of claim 10, wherein the semiconductor die is attached to the heat slug with a thermally conductive adhesive.

13. The electronics device of claim 10, wherein each second pin extends from the heat slug at a location external to the housing.

14. The electronics device of claim 10, wherein each second pin extends from or is thermally connected to the heat slug at a location internal to the housing.

15. The electronics device of claim 10, wherein the housing comprises an encapsulant formed over the semiconductor die.

16. The electronics device of claim 10, wherein the heat slug is disposed along a top portion of the housing.

17. The electronics device of claim 10, wherein a surface of the heat slug exposed, the surface configured for attachment of an external heat sink thereto.
